(19) United States
(12) Patent Application Publication
(10) Pub. No.: US 2015/0041186 A1
(43) Pub. Date: Feb. 12, 2015

(54) FIXING MEMBER AND MOUNTING DEVICE UTILIZING FIXING MEMBER FOR HEAT SINK

(71) Applicant: HON HAI PRECISION INDUSTRY CO., LTD., New Taipei (TW)

(72) Inventors: CHIH-TA HUANG, New Taipei (TW); CHUN-WEI KUAN, New Taipei (TW)

(73) Assignee: HON HAI PRECISION INDUSTRY CO., LTD., New Taipei (TW)

(21) Appl. No.: 13/968,440

(22) Filed: Aug. 16, 2013

(30) Foreign Application Priority Data
Aug. 6, 2013 (TW) 102128170

(51) Int. Cl. H05K 7/12

(52) U.S. Cl. CPC H05K 7/12
USPC 174/252; 24/453

(57) ABSTRACT

A fixing member for mounting a heat sink to a circuit board without screws includes a connecting portion through the heat sink and the circuit board, and a blocking portion connected to a bottom end of the connecting portion to latch in a bottom surface of the circuit board. A resilient portion connected to a top end of the connecting portion and bearing down on a top surface of the heat sink is deformable to enable the initial latching of the hooked portion in the bottom surface of the circuit board.

### BACKGROUND

1. Technical Field

The present disclosure relates to a heat sink mounting device.

2. Description of Related Art

Heat sinks need to be mounted to circuit boards by screws, which is time consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a mounting device together with a heat sink, wherein the mounting device includes two fixing members.

FIG. 2 is an assembled, isometric view of the mounting device together with heat sink of FIG. 1.

FIG. 3 is a cross-sectional view of the objects in FIG. 2, taken along the line III-III.

FIG. 4 is an isometric view of another embodiment of a fixing member.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

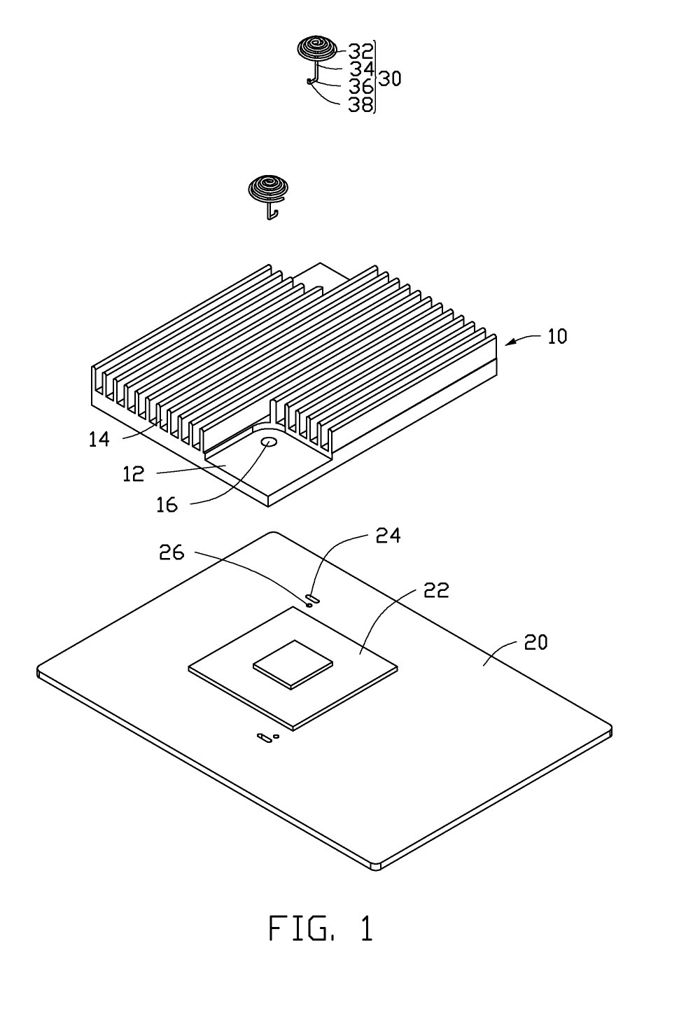

Referring to FIG. 1, an embodiment of a mounting device is provided for fixing a heat sink 10 to a circuit board 20. The mounting device includes two fixing members 30.

The circuit board 20 includes an electronic element 22 mounted on a top of the circuit board 20. The circuit board 20 defines two through holes 24, at opposite sides of the electronic element 22. An engaging hole 26 is defined in the circuit board 20, between each through hole 24 and the electronic element 22.

The heat sink 20 includes a base board 12 resting on the electronic element 22, and a plurality of fins 14 perpendicularly extending up from a top of the base board 12. The base board 12 defines two installing holes 16 corresponding to the through holes 24.

Each fixing member 30 includes a resilient portion 32, a connecting portion 34 extending down from the resilient portion 32, a blocking portion 36 extending out horizontally from a bottom end of the connecting portion 34, and an upturned engaging portion 38 extending upwards from a distal end of the blocking portion 34.

In the embodiment, the resilient portion 34 is a tapered spring, a diameter of which increases from top to bottom. The resilient portion 34 winds about the connecting portion 34 from top to bottom.

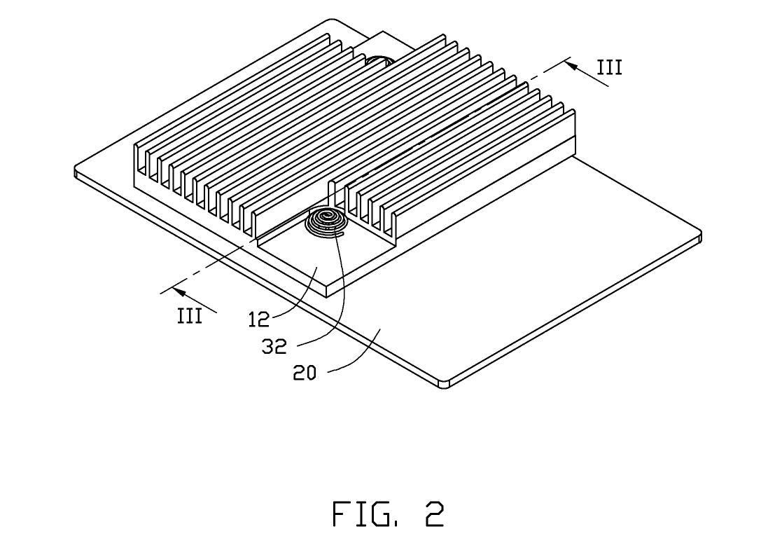

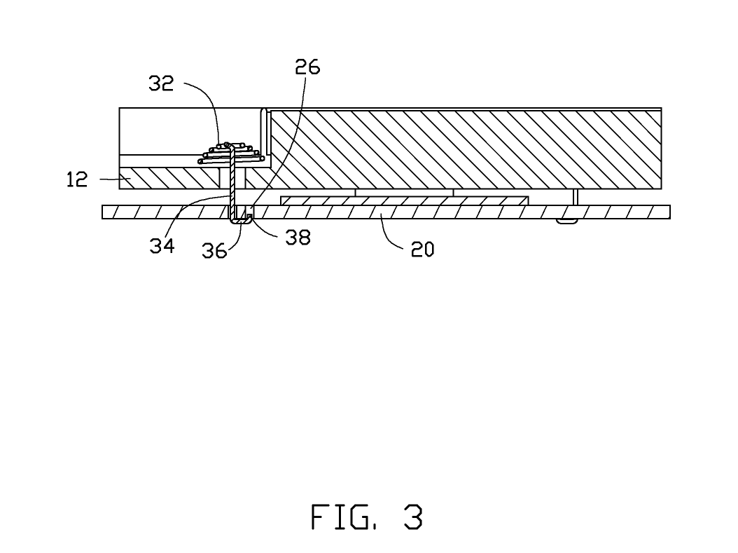

Referring to FIGS. 2 and 3, in assembly, the blocking portions 36 extend through the installing holes 16 and the through holes 24, until the blocking portions 36 are exposed out of a bottom of the circuit board 20. The resilient portions 32 are deformed and press down on the top of the base board 12. The fixing members 30 are then rotated, to manipulate the engaging portions 38 into alignment with the engaging holes 26. The fixing members 30 are released when the engaging portions 38 are engaged in the engaging holes 26. Thereby, the heat sink 10 is mounted on the circuit board 20.

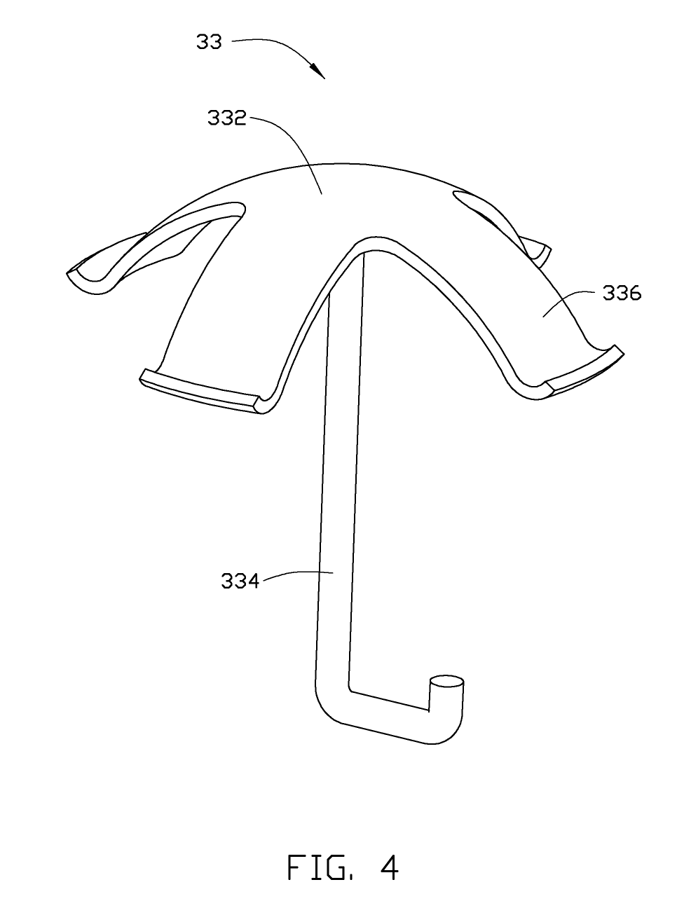

Referring to FIG. 4, in another embodiment, the resilient portion 332 of each fixing member 33 includes a plurality of arc-shaped resilient pieces 336 surrounding and connected to a top end of the connecting portion 334.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fixing member to fix a heat sink to a circuit board, the fixing member comprising:
a connecting portion to extend through the heat sink and the circuit board;
a blocking portion connected to a bottom end of the connecting portion to be abutted a bottom of the circuit board; and
a resilient portion connected to a top end of the connecting portion to be deformed and abutted a top of the heat sink.

2. The fixing member of claim 1, wherein the resilient portion is a tapered spring winding about the connecting portion from top to bottom, a diameter of the spring increases from top to bottom.

3. The fixing member of claim 1, further comprising an engaging portion extending up from a distal end of the blocking portion to engage in the circuit board from the bottom of the circuit board.

4. The fixing member of claim 1, wherein the resilient portion comprises a plurality of arc-shaped resilient pieces surrounding and connected to the top end of the connecting portion.

5. A mounting device to fix a heat sink, comprising:
a circuit board defining a plurality of through holes; and
a plurality of fixing members, each fixing member comprising:
a connecting portion to extend through the heat sink and one of the plurality of through holes;
a blocking portion connected to a bottom end of the connecting portion and abutted a bottom of the circuit board; and
a resilient portion connected to a top end of the connecting portion, being deformed and abutting a top of the heat sink.

6. The mounting device of claim 5, wherein each resilient portion is a tapered spring winding about the corresponding connecting portion from top to bottom, a diameter of the spring increases from top to bottom.

7. The mounting device of claim 5, wherein the circuit board defines an engaging hole adjacent to each through hole, each fixing member further comprises an engaging portion extending up from a distal end of the blocking portion to engage in the corresponding engaging hole from the bottom of the circuit board.

8. The mounting device of claim 5, wherein each resilient portion comprises a plurality of arc-shaped resilient pieces surrounding and connected to the top end of the corresponding connecting portion.
